(19) United States
(12) Patent Application Publication
(10) Pub. No.: US 2012/0288973 A1
(43) Pub. Date: Nov. 15, 2012

(54) DISPENSING METHOD AND DISPENSING APPARATUS

(75) Inventor: Masafumi Matsunaga, Yokohama-shi (JP)

(73) Assignee: Mtek-smart Corporation, Yokohama-shi, Kanagawa (JP)

(21) Appl. No.: 13/521,045

(22) PCT Filed: Jan. 7, 2011
(86) PCT No.: PCT/JP2011/050168

§ 371 Date: Jul. 7, 2012

(30) Foreign Application Priority Data
Jan. 8, 2010 (JP) 2010-003319

(51) Int. Cl. B05D 1/26; B05C 11/00; H01L 33/50; B05C 5/00

(52) U.S. Cl. 438/29; 427/424; 427/427.3; 118/300; 118/697; 257/E33.061

(57) ABSTRACT

Disclosed are a dispensing method and a dispensing apparatus for dispensing a coating material over an object to be applied by a dispensing device within a dispensing chamber including a top plate, a bottom plate and side plates, in which a fresh air inlet and an exhaust outlet are formed in an upper portion and a lower portion of the dispensing chamber, respectively; at least a discharge hole of the dispensing device is exposed to within the upper portion of the dispensing chamber;
an object mounting unit is set to be exposed to within the dispensing chamber from the side of the bottom plate. At least one of the dispensing device and an object mounting unit are movable linearly, and at least one of the dispensing device and an object mounting unit is moved by a driving mechanism disposed outside the dispensing chamber, thereby positioning the dispensing device with respect to the object to be applied and dispensing the coating material over the object with a dispensing device.

### TECHNICAL FIELD

The present invention relates generally to a method and an apparatus for applying a coating material over an object to be applied, and more particularly to a method and an apparatus for automatically applying a flammable coating material.

### BACKGROUND ART

Conventionally, for effecting a method of discharging a coating material containing a flammable organic solvent to form a pattern of lines as well as dots or aggregation thereof over an object to be applied, a large number of automatic dispensing apparatuses have hitherto been manufactured and employed in industries, the apparatus being configured by setting a dispensing tool in a biaxial or triaxial Cartesian coordinate robot.

Further, as a simple version thereof, a good number of desktop robots have been also manufactured and adopted in many industries, mainly in an electronics industry, the robot being configured by setting the dispensing tool such as a dispenser, a spray nozzle, an ultrasonic atomizing device and an inkjet discharger.

### DOCUMENT OF PRIOR ART

Patent document 1: Japanese Patent Application Laid-Open No. 2000-277129
Patent document 2: Japanese Patent Application Laid-Open No. 6-143063
Non-Patent document 1: HEISHIN Ltd.: Internet Website
Non-Patent document 2: Musashi Engineering, Inc.: Internet Website

### SUMMARY OF THE INVENTION

### Problems to be Solved by the Invention

For example, in the case of desiring to acquire a coated film of polymer over an object or substrate to be applied or coated, this involves preparing a solution obtained by dissolving the polymer etc with a flammable aromatic series organic solvent or hydrocarbon series organic solvent, and dispensing and spraying the solution over the object to be applied through the spray nozzle. Though possible by a manual operation, normally for obtaining reproducibility, the object to be applied is mounted on a table of the desktop robot equipped with a small-sized biaxial or triaxial driving shaft, and dispensing and spraying are performed. Thereafter, the organic solvent remaining over the coated object is forcibly volatilized by natural drying or by a dryer, thereby forming the coated film over the object. If a substance of the coated film is monomer etc such as a thermoset resin and a UV cured resin, it is required to effect hardening by heat or ultraviolet rays after having volatilized the organic solvent.

Further, the application of an adhesive containing the organic solvent involves conducting the same processing. For example, in a laboratory etc of the university or college, however, the operation is performed by placing a small-sized apparatus in a draft chamber equipped with an air intake/exhaust facility because of being small in treatment quantity of the solution etc, and hence it may be feasible to ignore influence of the volatile organic solvent on workers.

In the case of frequently performing the dispensing operations in a factory etc and dispensing a large quantity of solution etc, however, the dispensing operation is conducted by installing a dispensing apparatus equipped with the dispensing tool and a dispensing apparatus moving device and/or a table moving device in a booth enclosed by a box equipped with a comparatively large-sized air intake/exhaust system. In this case, a power motor, e.g., a servo motor as well as a stepping motor, which is used as a driving source that generates power, is exposed to the organic solvent or a vapor thereof and is therefore required to have an explosion-proof construction.

Generally, however, the explosion-proof motor is large in size and is, besides, heavy such as being twice or more in weight, and consequently the installation needs a large-sized frame with an increased strength. Moreover, in the case of adopting the biaxial Cartesian coordinate robot, a restraint arises in weight capacity of the shaft when one driving shaft supports the driving source. Further, normally the explosion-proof motor is a BTO (Build To Order) product to require 4 through 6 months up to an appointed date of delivery, which is hard to meet a requested quick delivery on the industry side.

For coping with this problem, there is simply adopted a method of putting the power source such as the motor into the box, then injecting the pressurized air therein to increase an air pressure and thus preventing infiltration of the solvent vapor. This method is not generally, however, approved based on demonstrative examination by a public institution and has a high risk in terms of self-responsibility.

Supposing that these simple internal pressure type apparatuses are expediently approved based on the responsibility of a client, it is required that pipes accommodate wires leading to the power source. As in the case of the biaxial Cartesian coordinate robot, if a necessity arises for moving the servo motor or the stepping motor defined as the power source, these apparatuses cannot be applied.

There is a case of approving a method of making a wire arrangement by use of an explosion-proof wiring connector, however, even when a cable rack normally used for the robot accommodates the wires, deterioration of the wire covering due to rubbing is inevitable, resulting in a risk causing sparks.

Furthermore, there is proposed a method of performing an air intake from within a chamber containing the solvent of which a concentration is much larger than twice of a lower limit of the explosion in a booth and performing the exhaust outside the chamber in order to avoid ignition to the solvent vapor due to the sparks caused by a cutoff of wire and an abnormal emission of heat caused by an overload on the power source. The solvent vapor is diluted as an air flow rate increases with the result that it is feasible to keep a level at which the ignition cannot be absolutely attained, however, an air speed in the booth rises, then particles escape as carried on the air especially in the case of conducting the spray-dispensing, and hence dispensing efficiency extremely decreases. For instance, a platinum catalyst used for forming an electrode of a fuel cell and YAG (yttrium aluminum garnet) phosphor used for coating the LED that is obtained by coating a blue light-emitting diode and emits white light, are highly expensive, and hence it is the present condition that the industry does not accept this method.

### Means for Solving the Problems

The present invention was devised to solve the problems described above and has for its object to provide a liquid dispensing method and a liquid dispensing apparatus that are superior in terms of a sealing property.

To solve the problems, the present invention provides a dispensing method of dispensing a coating material over an object to be applied or coated by a dispensing device within a dispensing chamber composed of a top plate, a bottom plate and side plates, the method including:

forming a fresh air inlet and an exhaust outlet in an upper portion and a lower portion of the dispensing chamber, respectively;

exposing at least a discharge hole of the dispensing device to within the upper portion of the dispensing chamber;

installing an object mounting unit to be exposed to within the dispensing chamber from the side of the bottom plate and configuring the dispensing device and an object mounting unit so as to enable at least one of the dispensing device and the object mounting unit to move linearly; and

moving at least one of the dispensing device and the object mounting unit with a driving mechanism provided outside the dispensing chamber and positioning the dispensing device with respect to the object to be applied, and dispensing the coating material over the object to be applied by the dispensing device.

In the dispensing method according to the present invention, it is preferable that the dispensing chamber takes a box-like shape, an upper portion of the dispensing chamber is formed with the fresh air inlet, and a lower portion of the dispensing chamber is formed with the exhaust outlet,

a first aperture extending in a first linear direction is formed in the top plate, and a second aperture extending in a second linear direction orthogonal to the first linear direction is formed in the bottom plate,

the driving mechanism includes a first driving device that is provided above the top plate and outside the dispensing chamber for moving the dispensing device in the first linear direction and a second driving device provided below the bottom plate and outside the dispensing chamber and serving to move the object mounting unit in the second linear direction,

the object mounting unit is exposed to within the dispensing chamber through the second aperture of the bottom plate,

a first movable body is provided to be moved in the first linear direction by the first driving device;

a first bracket is provided at the first movable body and extends into the dispensing chamber through the first aperture of the top plate;

first sealing means is provided between the top plate and the first bracket to seal the first aperture;

a dispensing device assembly equipped with the dispensing device is fitted to the first bracket within the dispensing chamber;

second sealing means is provided between the bottom plate and the object mounting unit to seal the second aperture; and

a control device is provided outside the dispensing chamber to control the first and second driving devices;

wherein the object to be applied is disposed on the object mounting unit within the dispensing chamber, the dispensing chamber exclusive of the fresh air inlet and the exhaust outlet is sealed, the control device controls the first and second driving devices or positions the dispensing device with respect to the object to be applied by a programmed operation, and the dispensing device dispenses the coating material over the object to be applied.

In the dispensing method according to the present invention, it is preferable that at least one of the side plates is provided with an opening/closing door for accessing the interior of the dispensing chamber,

the object mounting unit includes: a second movable body that is moved in the second linear direction by the second driving device; a second bracket provided at the second movable body and extending into the dispensing chamber through the second aperture of the bottom plate; and an object mounting table is fitted to the second bracket, and

the object to be applied is disposed on the object mounting unit within the dispensing chamber via the opening/closing door.

In the dispensing method according to the present invention, it is preferable that the object mounting unit includes a belt conveyor that is moved in the second linear direction by the second driving device, and the object to be applied is placed on the belt conveyer and is disposed within the dispensing chamber.

Further, in order to solve the problems given above, in the dispensing method according to the present invention, it is preferable that the dispensing chamber configures a cylindrical or polygonal box body including the top plate and the side plates and fixedly disposed to open downward, the bottom plate being disposed on the lower side of the box body and enabled to make linear motions at the same height with the box body in the first direction and in the second direction orthogonal to the first direction in a contact or non-contact state with the side plate,

a dispensing device is disposed above the top plate, of which at least a discharge hole is exposed to within the dispensing chamber,

the object mounting unit includes a table covering a whole area of the central aperture of the bottom plate, the table being fixedly disposed onto the bottom plate and exposed to within the dispensing chamber and moved together with the bottom plate, the table being moved in the first linear direction and the second linear direction by the first driving device and the second driving device each provided outside the dispensing chamber,

the first and second driving devices position the dispensing device with respect to the object to be applied by a programmed operation, and

the dispensing device dispenses the coating material over the object to be applied.

In the dispensing method according to the present invention, it is preferable that the dispensing device is moved in the vertical direction by the second driving mechanism disposed outside the dispensing chamber.

In the dispensing method according to the present invention, it is preferable that the coating material is slurry composed of a phosphor, a binder and a solvent, and

the slurry is moved by a pressure difference between two or small-sized containers or/and circulated by use of a pump and is dispensed by the dispensing device consecutively or pulsewise over an LED mounted on the temperature-controlled object mounting unit.

In the dispensing method according to the present invention, it is preferable that a circulation circuit is configured by establishing communicating paths among one small-sized container, the dispensing device and a small-sized pump to circulate the slurry filling the small-sized container and pressurized by a compressed gas, and

the dispensing device dispenses the coating material consecutively or pulsewise over the LED mounted on the temperature-controlled object mounting unit.

Still further, in order to solve the problems, the present invention provides a dispensing apparatus configured to dispense a coating material over an object to be applied by a dispensing device within a dispensing chamber including a top plate, a bottom plate and side plates, the dispensing apparatus comprising:

a fresh air inlet and an exhaust outlet being formed in an upper portion and a lower portion of the dispensing chamber, respectively;

the dispensing device getting at least its discharge hole exposed to within the dispensing chamber;

an object mounting unit being disposed to be exposed to within the dispensing chamber from the side of the bottom plate; and

a driving mechanism being provided outside the dispensing chamber and driving at least one of the dispensing device and the object mounting unit,

wherein the dispensing device is positioned with respect to the object to be applied and dispenses a coating material over the object to be applied.

In the dispensing apparatus according to the present invention, it is preferable that the dispensing chamber takes a box-like shape, the fresh air inlet is formed in any one of the top plate and the vicinity of the top plate, and the exhaust outlet is formed in the bottom plate and the vicinity of the bottom plate,

a first aperture extending in a first linear direction is formed in the top plate, and a second aperture extending in a second linear direction having an orthogonal relation with the first linear direction is formed in the bottom plate,

the driving mechanism is provided above the top plate and outside the dispensing chamber and includes a first driving device for moving the dispensing device in the first linear direction and a second driving device provided below the bottom plate and outside the dispensing chamber and serving to move the object mounting unit in the second linear direction,

the object mounting unit is exposed to within the dispensing chamber through the second aperture of the bottom plate,

the dispensing apparatus further includes:

a first movable body that is moved in the first linear direction by the first driving device;

a first bracket provided at the first movable body and extending into the dispensing chamber through the first aperture of the top plate;

first sealing means provided between the top plate and the first bracket and sealing the first aperture;

a dispensing device assembly fitted to the first bracket within the dispensing chamber and including the dispensing device

second sealing means provided between the bottom plate and the object mounting unit and sealing the second aperture; and

a control device provided outside the dispensing chamber and controlling the first and second driving devices,

wherein the object to be applied is disposed on the object mounting unit within the dispensing chamber, the dispensing chamber exclusive of the fresh air inlet and the exhaust outlet, is sealed, the first and second driving devices are controlled by the control device or operated by programming to position the dispensing device with respect to the object to be applied, and the dispensing device dispenses the coating material over the object to be applied.

In the dispensing apparatus according to the present invention, it is preferable that at least one of the side plates is provided with an opening/closing door for accessing the interior of the dispensing chamber,

the object mounting unit includes: a second movable body that is moved in the second linear direction by the second driving device; a second bracket provided at the second movable body and extending into the dispensing chamber through the second aperture of the bottom plate; and an object mounting table fitted to the second bracket, and

the object to be applied is disposed on the object mounting unit within the dispensing chamber via the opening/closing door.

Yet further, in the dispensing apparatus according to the present invention, it is preferable that the object mounting unit includes a belt conveyor that is moved in the second linear direction by the second driving device, on which belt conveyer the object to be applied is placed and is disposed within the dispensing chamber.

Moreover, in the dispensing apparatus according to the present invention, it is preferable that the dispensing chamber configures a box body including the top plate and the side plates and fixedly disposed to open downward, the bottom plate being disposed on the lower side of the box body and enabled to make linear motions with respect to the box body in a first horizontal direction and in a second horizontal direction in a contact or non-contact state with the side plates,

the dispensing device is disposed above the top plate and gets at least its discharge hole exposed to within the dispensing chamber, and

the object mounting unit includes a table that covers a whole area of the central aperture of the bottom plate, and is fixed to the bottom plate to be exposed to within the dispensing chamber, the table being moved together with the bottom plate and movable in the first linear direction and the second linear direction by the first driving device and the second driving device each provided outside the dispensing chamber.

In the dispensing apparatus according to the present invention, it is preferable that the dispensing apparatus further includes a second driving mechanism disposed outside the dispensing chamber and moving the dispensing device in the vertical direction.

In the dispensing apparatus according to the present invention, it is preferable that the coating material is slurry composed of a phosphor, a binder and a solvent, and

the slurry is moved by a pressure difference between two or small-sized containers or/and circulated by use of a pump and dispensed by the dispensing device consecutively or pulsewise over an LED mounted on the temperature-controlled object mounting unit.

In the dispensing apparatus according to the present invention, it is preferable that a circulation circuit is configured by establishing communicating paths among one small-sized container, the dispensing device and a small-sized pump to circulate the slurry filling the small-sized container and pressurized by a compressed gas, and

the dispensing device dispenses the coating material consecutively or pulsewise over the LED mounted on the temperature-controlled object mounting unit.

According to the method or the apparatus of the present invention, the X-, Y- and Z-directional driving motors as well as the X-, Y- and Z-directional power transmission mechanisms are installed outside the dispensing chamber, then only the dispensing device assembly to be driven and the object mounting unit may be installed within the dispensing chamber, and hence there is no necessity for installing the electric wires and electric devices within the dispensing chamber, thereby acquiring the excellent sealing structure.

In the preferable mode of the present invention, the X-, Y- and Z-directional driving motors as well as the X-, Y- and Z-directional power transmission mechanisms and also the dispensing device assembly are installed outside the dispensing chamber, and only the aperture portion of the discharge nozzle provided in the dispensing device assembly is exposed to within the dispensing chamber, and, if thus configured, it is feasible to adopt inkjet type and electromagnetic valve direct drive type dispensing guns that cannot be normally used in the booth as valves of the components of the dispensing device assembly because of their non-explosion-proof constructions, and, for example, a combinational use of the high-speed electromagnetic valve and a special controller enables the pulse dispensing at the speed as high as, e.g., 50-1000 Hz.

### BRIEF DESCRIPTION OF THE DRAWINGS

FIG. 1 is a schematic front view of a dispensing apparatus according to a first embodiment of the present invention.

FIG. 2 is a schematic rear view of the dispensing apparatus according to the first embodiment of the present invention.

FIG. 3 is a schematic sectional view of the dispensing apparatus according to the first embodiment of the present invention as viewed from the front.

FIG. 4 is a schematic sectional view of the dispensing apparatus according to the first embodiment of the present invention as viewed from the left side.

FIG. 5 is a schematic sectional view of the dispensing apparatus according to the first embodiment of the present invention as viewed from the right side.

FIG. 6A is a schematic partial sectional view illustrating a Y-directional moving device and Y-directional moving device of the dispensing apparatus according to the first embodiment of the present invention; and FIG. 6B is an schematic explanatory view illustrating another example of a dispensing device assembly used in the dispensing apparatus according to the first embodiment of the present invention.

FIG. 7 is a schematic sectional view of the dispensing apparatus, which is taken along the line vii-vii in FIG. 1.

FIG. 8 is a schematic partial sectional view of a dispensing booth for explaining particularly a Y-directional moving mechanism of the dispensing apparatus according to the first embodiment of the present invention.

FIG. 9 is a schematic view of an apparatus body, which is taken along the line ix-ix in FIG. 1.

FIG. 10 is a schematic partial front view illustrating a configuration of an X-directional movable body of the dispensing apparatus according to the first embodiment of the present invention as viewed from the front.

FIG. 11 is a schematic partial plan view illustrating the configuration of the X-directional movable body of the dispensing apparatus according to the first embodiment of the present invention.

FIG. 12 is an explanatory view of a roller and a rail of the X-directional movable body of the dispensing apparatus according to the first embodiment of the present invention.

FIG. 13 is a schematic partial side view illustrating configurations of an object mounting table and the Y-directional movable body of the dispensing apparatus according to the first embodiment of the present invention.

FIG. 14 is a schematic sectional view of an interior of the dispensing apparatus according to a second embodiment of the present invention as viewed from the front.

FIG. 15 is a schematic sectional view of the interior of the dispensing apparatus according to the second embodiment of the present invention as viewed from sideway.

FIG. 16 is a schematic sectional view of the interior of the dispensing apparatus according to a third embodiment of the present invention as viewed from the front.

FIG. 17 is a schematic sectional view of the interior of the dispensing apparatus according to the third embodiment of the present invention as viewed from sideway.

### MODE FOR CARRYING OUT THE INVENTION

An exemplary embodiment of the present invention will hereinafter be described with reference to the drawings. Each of the following embodiments is nothing but one example for facilitating the understanding of the invention, and it is not an exclusive matter to make additions, replacements, modifications, etc, which can be carried out by those skilled in the art within the range that does not deviate from the technical idea of the present invention.

The drawings schematically illustrate the exemplary embodiment of the present invention.

### First Embodiment

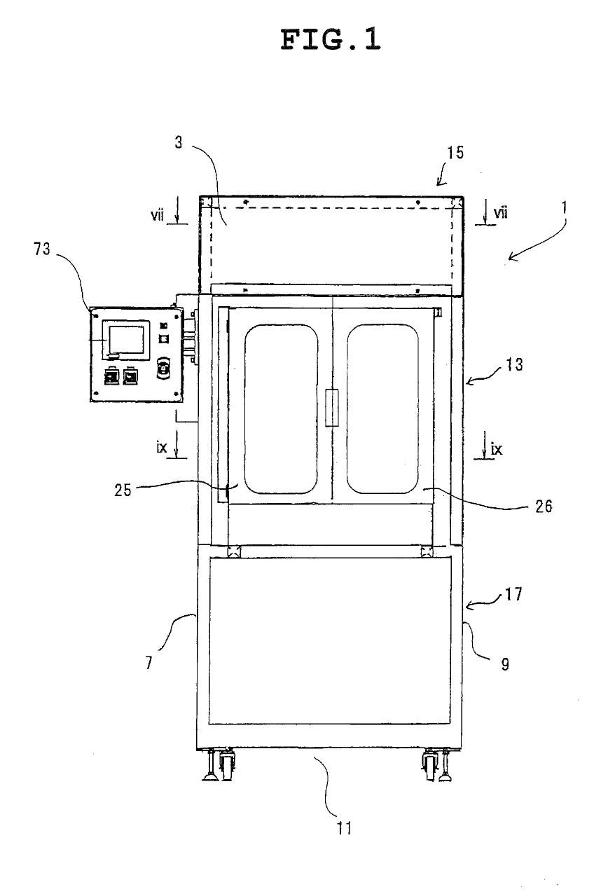

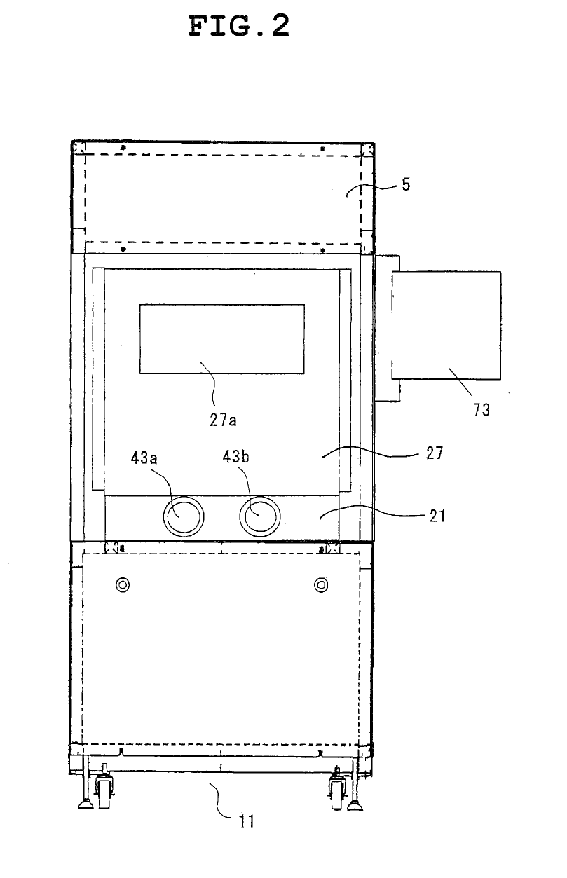

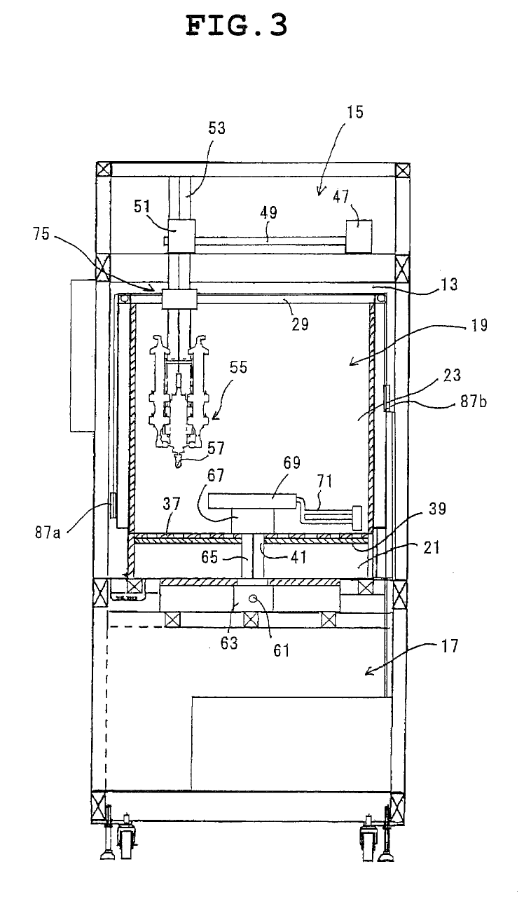

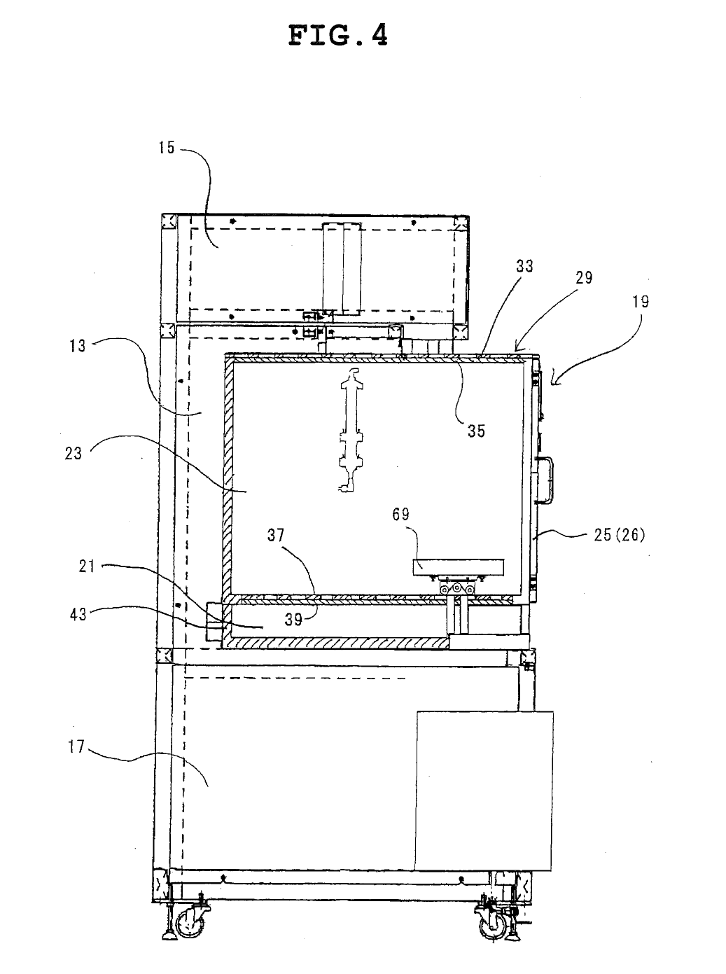

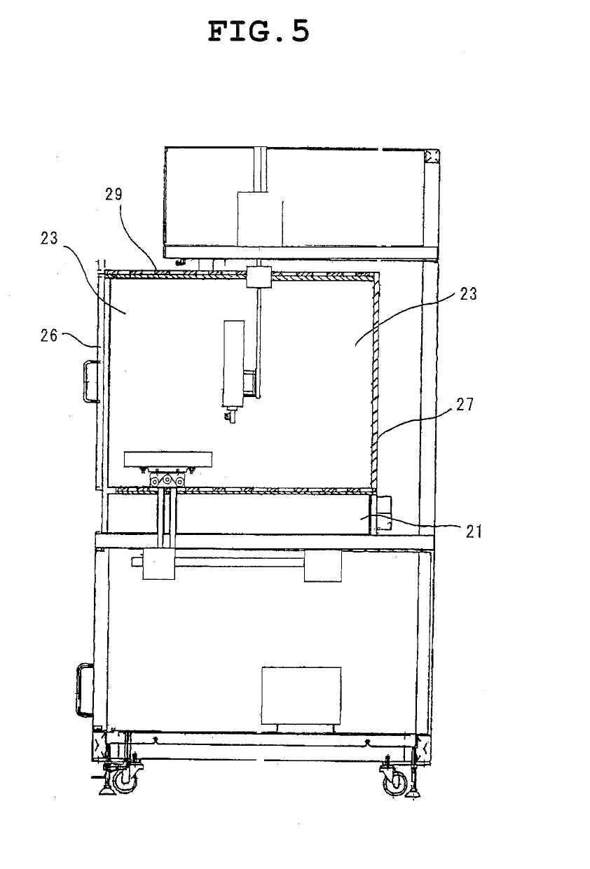

FIGS. 1 to 5 illustrate a dispensing apparatus according to a first embodiment of the present invention; FIG. 1 is a front view of the dispensing apparatus; FIG. 2 is a rear view of the dispensing apparatus; FIG. 3 is a sectional view of the dispensing apparatus as viewed from the front; FIG. 4 is a sectional view of the dispensing apparatus as viewed from the left side; and FIG. 5 is a sectional view of the dispensing apparatus as viewed from the right side. In the discussion on the first embodiment, a Y-direction is set in a back-and-forth direction with respect to the sheet surface in FIG. 1, and an X-direction is set in a right-and-left direction.

The dispensing apparatus in the first embodiment includes an apparatus body 1 taking substantially a cubic shape that is long in a vertical direction on the whole, and the apparatus body includes a front portion 3, a rear plate 5, a left side plate 7, a right side plate 9, a bottom portion 11 and an top portion.

The apparatus body 1 is roughly sectioned into three parts in the vertical direction, in which a dispensing booth setting chamber 13 is formed at the center in the vertical direction, an upper chamber 15 is formed above or on the upper side of the dispensing booth setting chamber 13, a lower chamber 17 is formed below or at the lower side of the dispensing booth setting chamber 13, and a dispensing booth 19 within the dispensing booth setting chamber 13 is isolated from the upper chamber 15, the lower chamber 17 and the periphery thereof by a sealing structure. (The sealing structure in the specification connotes having such a degree of airtightness that a leakage of a flammable gas within the dispensing booth 19 or a dispensing chamber 23 that will be described later on is not enough to cause an explosion outside the dispensing booth 19 or the dispensing chamber 23).

The dispensing booth 19 is a box-shaped body configured by a hexahedron having six faces on the front and rear sides, the left and right sides and the upper and lower sides and is sectioned into an exhaust chamber 21 formed in the lower portion and the airtight dispensing chamber 23 formed above the exhaust chamber 21. Two doors 25, 26, which open on both sides, are provided on the front side of the airtight dispensing chamber 23, thereby enabling an access to be made from the outside. A rear plate member 27 on the rear side of the dispensing booth 19 is formed with a transparent glass window 27a.

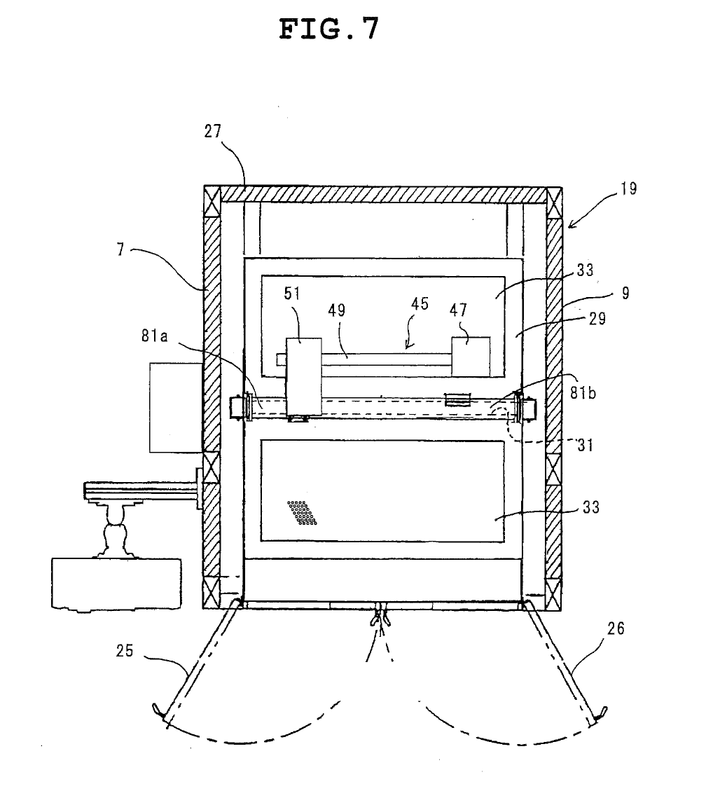

As depicted by a dotted line in FIG. 7, a top plate member 29 forming the top portion of the dispensing booth 19, i.e., the top portion of the dispensing chamber 23 extends to a predetermined length in the X-direction at the central portion in the back-and-forth direction (the Y-direction) and is formed with an aperture 31 having the same width over its overall length.

The top plate member 29 includes perforated plates 33 such as punched plates provided on both sides of the central aperture 31, and a filter 35 is spreaded over removably inside the chamber (see FIG. 4). The filter 35 is exemplified by an air filter used in a clean room in order to remove wastes and dusts contained in the external air, and, for example, a HEPA (High Efficiency Particulate Air) filter is preferable. Thus, the top plate member 29 is formed with the fresh air inlet or intake portions on the both sides of the central aperture 31.

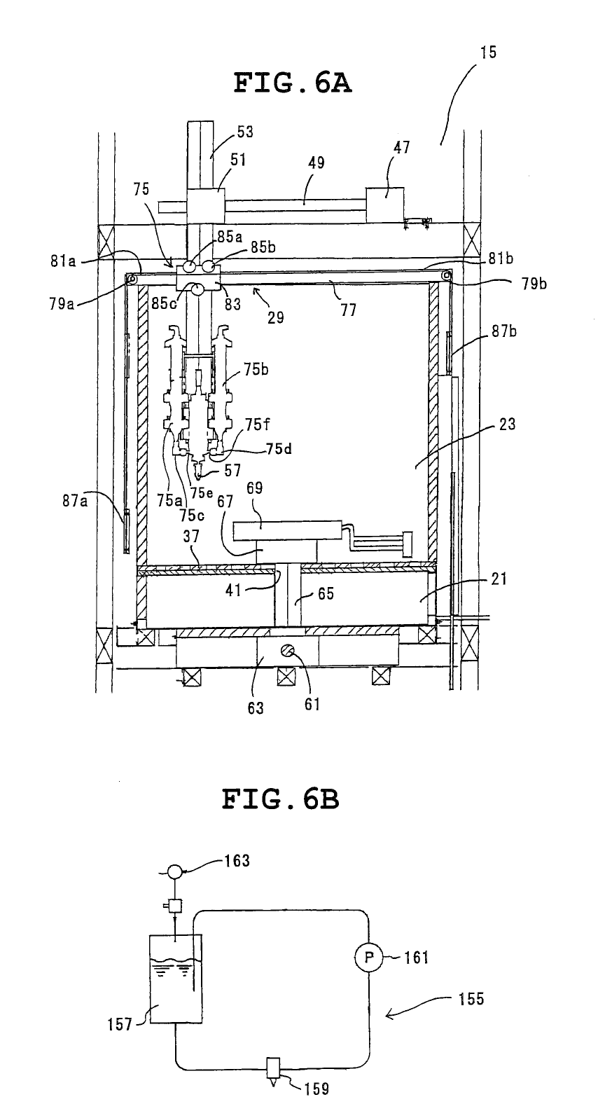

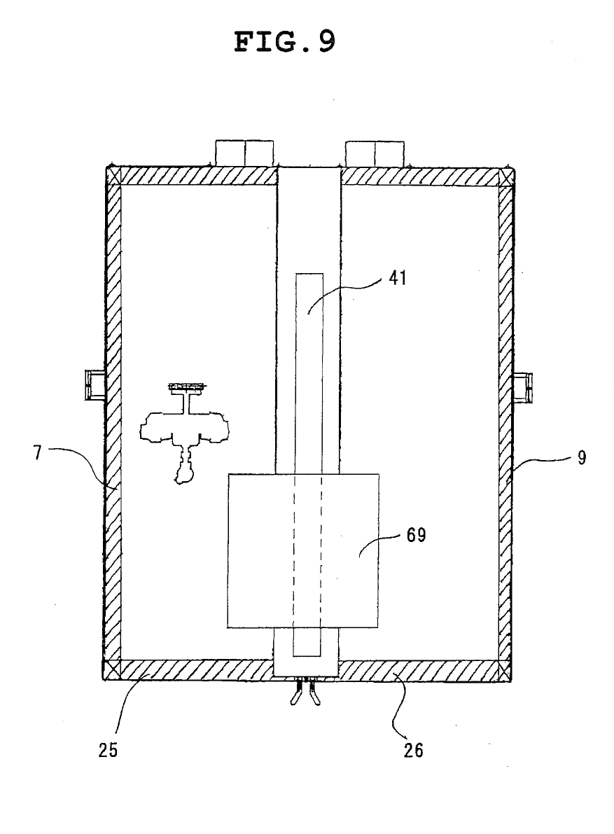

In the dispensing booth 19, as illustrated in FIG. 4, a metal perforated plate 37 is extended over between the dispensing chamber 23 and the exhaust chamber 21, and a filter 39 is spreaded over removably on the underside thereof. The metal perforated plate 37 is preferably the punched plate, and the filter 39 is preferably a non-flammable filter composed of a glass fiber etc or a fire-resisting felt web plate composed of flame resisting aramid in a way that takes a flammable solvent to be used into consideration. An aperture 41 (see FIGS. 6a and 9) having a predetermined width is formed to extend in the Y-direction at the X-directional center of the metal perforated plate 37 in the lower portion of the dispensing chamber 23. This Y-directional aperture 41 will be described later on.

The rear plate member 27 is formed with two right and left exhaust ports 43a, 43b (see FIG. 2) at the rear portion of the exhaust chamber 21, to which an exhaust device (unillustrated) is connected.

### <X-Directional Movable Body Structure of Upper Portion>

An X-directional driving device 45 extending in the X-direction is, as depicted in FIG. 7, provided over between the right/left side plates 7, 9 in a position deviating from an upper position substantially opposed to or in a face-to-face relation with the aperture 31 of the top plate member 29 within the upper chamber 15 of the apparatus body 1. The X-directional driving device 45 includes a drive motor 47 and a converting mechanism for converting rotations of the drive motor 47 into reciprocating linear motions. This converting mechanism includes a ball screw shaft 49 rotationally driven by the drive motor 47 and extending in the right and left direction and a movable body 51 engaging with the ball screw shaft 49 and fitted with a nut that moves in the X-direction.

As illustrated in FIG. 3, the movable body 51 has a portion extending in the opposed or face-to-face relation with the position just above the X-directional aperture 31 of the top plate member 29 of the dispensing chamber, and an upper bracket 53 extending in the vertical direction from the upper chamber 15 into the dispensing chamber 23 is fixedly provided at this portion. The upper bracket 53 extends to substantially the central portion in the vertical direction within the dispensing chamber 23, and a dispensing device assembly 55 is fitted to a lower end portion of the upper bracket 53. Such being the structure, the operation of the X-directional driving device 45 enables the dispensing device assembly 55 and a dispensing device including a discharge nozzle 57 to move in the X-direction within the dispensing chamber 23.

Details of the dispensing device assembly 55 will be described later on. Further, the interior of the dispensing chamber 23 and the upper chamber 15 are isolated from each other by the sealing structure, and hence the upper bracket 53 is structured to be movable in the X-direction with respect to the top plate member 29 and to air-tightly be in contact therewith, however, this structure will be described in detail later on.

### <Y-Directional Movable Body Structure of Lower Portion>

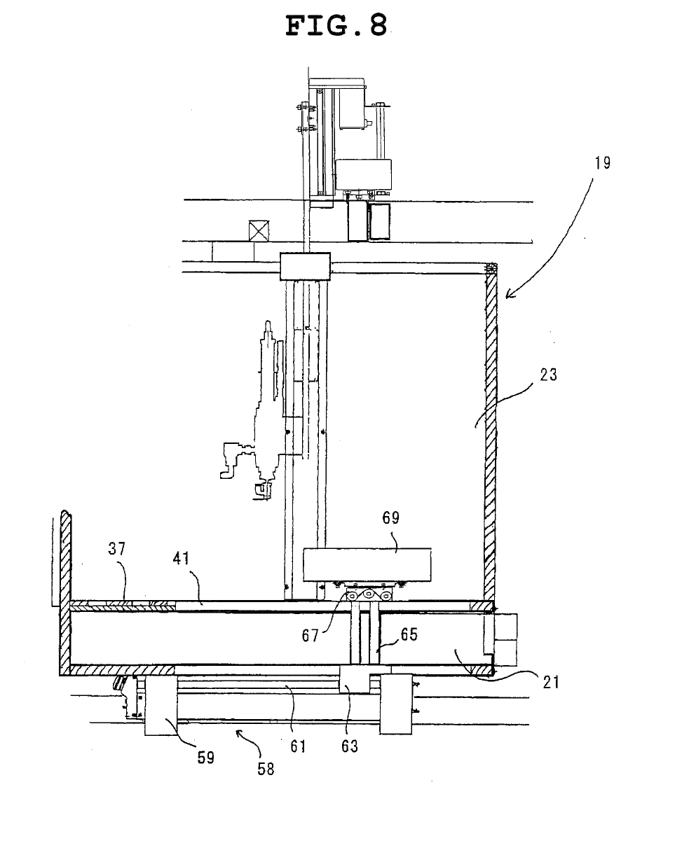

A Y-directional driving device 58 extending to a predetermined length in the Y-direction in a position in the opposed or face-to-face relation with the Y-directional aperture 41 of the metal perforated plate 37 which is for the partition between the dispensing chamber 23 and the exhaust chamber 21, is provided within the lower chamber 17 of the apparatus body 1 (see FIG. 8). The Y-directional driving device 58 includes a drive motor 59 and a converting mechanism for converting the rotations of the drive motor 59 into the reciprocating linear motions. This converting mechanism includes a ball screw shaft 61 rotationally driven by the drive motor 59 and extending in the Y-direction and a movable body 63 engaging with the ball screw shaft 61 and fitted with a nut that moves in the Y-direction. The Y-directional movable body 63 is fixed to a lower bracket 65 extending upward through the Y-directional aperture 41 of the metal perforated plate 37 that is the bottom plate member of the dispensing chamber 23. The lower bracket 65 has an upper end at the lower portion within the dispensing chamber 23 (see FIG. 6A). A box-shaped body 67 having larger in width than the Y-directional aperture 41 is fixedly provided at the upper end of the lower bracket 65, and a table 69 for mounting an object to be coated, which configures an object mounting unit, is fitted onto the box body 67. Such being the structure, the operation of the Y-directional driving device 58 enables the object mounting table 69 to move in the lower portion within the dispensing chamber 23 in the Y-direction. The object mounting table 69 is enabled to adjust a temperature through a heat carrier circulation cord 71. The cord 71 is guided to a heat source of the lower chamber 17. Note that the object mounting unit may involve using a belt conveyor equipped with a drive source outside the booth. The belt conveyor passes through the lower portion within the booth via an inlet/outlet of a slight gap in the Y-direction, and can circulate via the bottom portion of the apparatus. For example, in the case of coating a web such as a film which continuously moves, a coating material is not adhered to the underside of the film by bringing the film into sufficient contact with the conveyor substantially at the same speed.

The interior of the dispensing chamber 23 and the exhaust chamber 21 are isolated from each other by the sealing structure, and hence the Y-directional bracket 65 is movable in the Y-direction with respect to the metal perforated plate 37 and air-tightly is in contact therewith, however, this structure will be described in detail later on.

As illustrated in FIG. 1, in the first embodiment, the left side plate 7 of the apparatus body 1 is fitted with a control box 73, a front surface of the control box 73 is provided with a display unit and a power switch, and an interior thereof is provided with a control circuit including a CPU etc, and the two driving devices 45, 58 in the X- and Y-directions undergo the pre-programmed control. Therefore, the X-directional drive motor 47 and the Y-directional drive motor 59 are connected to the control circuit of the control box via cables respectively, however, their illustrations are omitted because of their being complicated.

In the present embodiment and the second and third embodiments that will hereinafter be described, the dispensing apparatus is preferable for dispensing polymer onto the object to be coated and is preferable for dispensing the polymer etc with a solution dissolved by a flammable aromatic series organic solvent as well as hydrocarbon series organic solvent, and the dispensing device assembly 55 is equipped with, as disclosed in, e.g., Japanese Patent Application Laid-Open No. 2003-300000, two syringe-shaped containers 75a, 75b (see FIG. 6A), flow passages 75c, 75d for making these containers communicate with each other, flow rate adjusting means 75e, 75f for each adjusting a flow rate of a liquid flowing through the flow passage, and a discharge nozzle 57 which pulsewise or consecutively discharges slurry from the flow passage. The slurry is a mixture of phosphor particles and a binder solution composed of the polymer or monomer and the solvent, and is covering over a blue light-emitting diode etc for emitting white light, and the two syringe-shaped containers 75a, 75b are filled with the slurry. A pressure difference is given to these two syringe-shaped containers 75a, 75b to generate a flow of slurry through the flow passage, and the slurry is discharged pulsewise or consecutively from the discharge nozzle 57. At this time, the object to be coated such as the LED is properly heated up by the object mounting table 69 (FIG. 6A).

In the first embodiment, the control and the drive of the dispensing apparatus are conducted all by compressed air. Therefore the syringe-shaped containers, the discharge opening/closing means and the discharge nozzle are respectively connected to an air source via pipes (unillustrated). The pipes are preferably guided together with the upper bracket 53 to the outside of the dispensing chamber. Incidentally, another available configuration is that the circulation, without being limited to the circulation based on the two syringes, is attained by arranging a tube up to the dispensing device assembly by use of a small-sized container of one syringe and a small-sized pump. For instance, a dispensing device assembly 155 as depicted in FIG. 6B is employed as a substitute for the dispensing device assembly 55. The dispensing device assembly 155 forms a slurry circulation circuit by connecting a small-sized container 157 to be filled with the slurry, a discharge nozzle 159 and a pump 161 with tubes, whereby the slurry within the small-sized container 157 pressurized by an air source 163 is flowed to within the circulation circuit by the pump 161 and is discharged pulsewise or consecutively from the discharge nozzle 159. At this time, the object to be coated such as the LED is properly heated up by the object mounting table 69 (FIG. 6A).

An in-depth description of the sealing structure between the dispensing chamber 23 and the upper bracket 53 as the movable portion for the X-directional movement in the first embodiment will hereinafter be made with reference to, particularly, FIGS. 6A through 13.

### <Sealing Structure of X-Directional Movable Body of Upper Portion>

Referring to FIG. 6A, at the X-directional aperture 31 of the top plate member 29 of the dispensing chamber 23, the upper bracket 53 for the X-directional movement described above is provided with a movable body unit 75 movable in the X-direction (the right and left direction) along the X-directional aperture 31 formed in the top plate member 29 of the dispensing chamber 23. In the first embodiment, the movable body unit 75 is air-tightly fixed to the upper bracket 53 to take the sealing structure because of no vertical motions of the upper bracket 53.

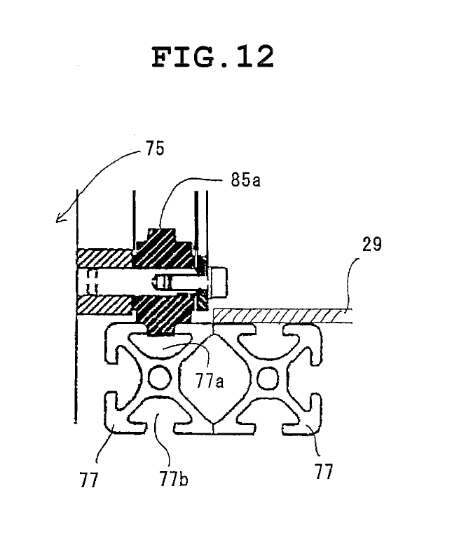

Rail members 77 each taking a sectional shape as illustrated in enlargement in FIG. 12 and extending in the X-direction are bridged over between the right and left side plate 7 and 9 along the edge portions of the X-directional aperture 31 and on the inside of the top plate member 29 within the dispensing chamber 23. Only a part of the right side of the aperture 31 is illustrated in FIG. 12. Each rail member 77 has a sectional shape in which two letters “X” are arranged in a side-by-side relation, then extends over between the right and left side plates 7 and 9 in the X-direction and is fixed to the dispensing chamber 23. Each rail member 77 is in contact with an internal face of the top plate member 29 on the upper side of one portion taking the X-shape in section, which one portion is located on the side apart from the X-directional aperture 31, while the other X-shaped sectional portion is exposed to the X-directional aperture 31, thereby forming track grooves 77a, 77b extending over the full length of the aperture in the X-direction in the upper and lower surfaces, respectively.

On the other hand, as illustrated in FIG. 6A, guide rollers 79a, 79b extending in a widthwise direction of the aperture 31 are disposed at both of right and left end portions of the X-directional aperture 31 of the top plate member 29 of the dispensing chamber, and right and left belts 81a, 81b are disposed to extend in the X-direction astride these guide rollers 79a, 79b to be movable in the X-direction. As depicted in FIG. 7, the belts 81a, 81b have widths (a Y-directional size) each larger than a width (a Y-directional size) of the X-directional aperture 31, respectively are in contact with both marginal edges of the aperture of the top plate member 29 on the both sides in the widthwise direction, thus covering the upper portion of the X-directional aperture 31. It is preferable that the belts each is a steel belt, a resin belt, etc, and, though not particularly limited to a type of the material, the preferable belt is a belt that is hard to produce the dusts and composed of a conductive material in terms of taking a measure against the static electricity.

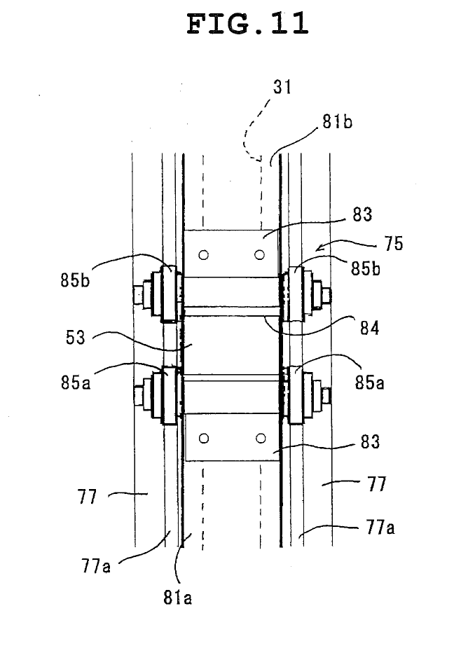

Referring to FIG. 6A, the upper bracket 53 extending from the upper chamber 15 into the dispensing chamber 23 and used for the X-directional movement is fixed to upper end portions of the two belts 81a, 81b via a fixing member 83. Therefore, the fixing member 83 taking a square shape is fixed by screws at four corners to the upper end portions of the belts, has an aperture 84 (see FIG. 11) at the center through which the upper bracket 53 extends in the vertical direction. The fixing member 83 has also a portion extending upward along the upper bracket 53 on both sides of the aperture 84, and is fixed to the upper bracket 53 at this portion. A portion between the fixing member 83 and the upper bracket 53 is sealed by a sealing means.

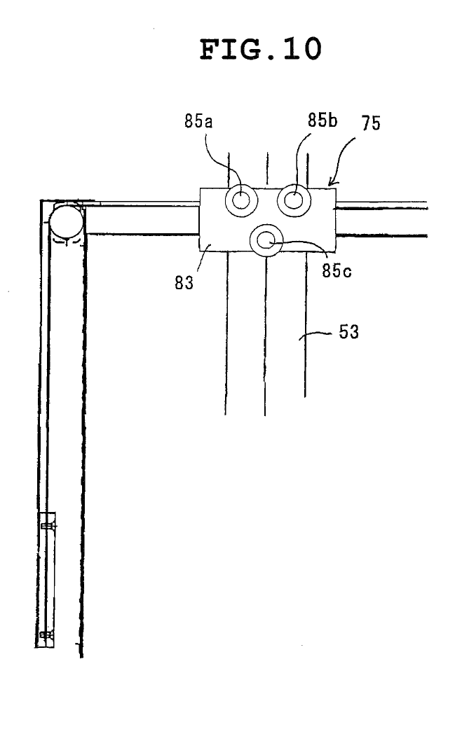

As depicted in FIG. 10, two rollers 85a, 85b spaced away from each other in the X-direction are rotatably supported on the upper portion of the fixing member 83 on both sides in the belt widthwise direction and, as illustrated in FIG. 11, engage with corresponding upper track grooves 77a provided right and left. Rollers 85c (see FIG. 10) are rotatably supported one by one on the central portion in the X-direction on both sides in the belt widthwise direction at the lower portion of the fixing member 83, and engage with corresponding track grooves 77b (see FIG. 12) provided right and left.

As illustrated in FIGS. 3 and 6A, the right and left ends of the right and left belts 81a, 81b extend downward along the right/left side plates of the dispensing booth 19 and are pulled by tension springs or proper weights 87a, 87b at the respective end portions so as not to slacken irrespective of the reciprocating movements in the X-direction of the movable body unit 75. The dispensing chamber 23 is thus sealed from the upper chamber 15.

Such being the structure, the X-directional aperture 31 is configured to take the sealing structure in the way of being sealed by the belts 81a, 81b regardless of the movements of the movable body unit 75, and besides the movements in the X-direction of the movable body unit 75 get stabilized by the rail members 77.

In the conventional dispensing apparatus, the air is sucked naturally from the aperture portion by the forcible exhaust, and hence such a possibility extremely rises that when the dispensing apparatus is installed in an atmosphere other than the clean room, foreign matters such as the dusts are absorbed and adhered to the object to be coated, resulting in an extremely high possibility of causing a decline of quality of the coated object. Further, the flow of intake air from the aperture portion causes a turbulent flow in the vicinity of the object to be coated, which becomes a critical defect if the dispensing device is a spray device. In this respect, the dispensing apparatus according to the first embodiment can solve these problems because the aperture portion can be sealed by the belts 81a, 81b.

### <Sealing Structure of Y-Directional Movable Body of Lower Portion>

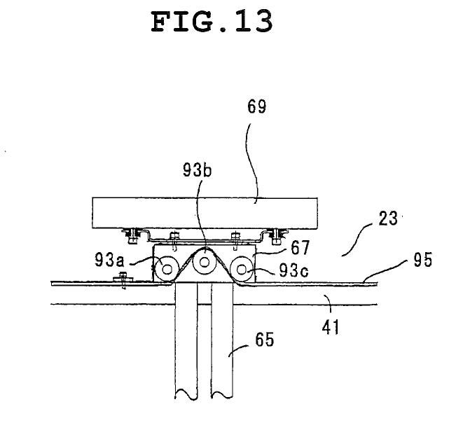

As illustrated in detail in FIG. 8, the lower bracket 65 is fixed to the Y-directional movable body 63 within the lower chamber 17 of the apparatus body 1 and extends upward into the dispensing chamber 23 (FIG. 13). The box body 67 is elongated in the Y-direction on the upper side of the Y-directional aperture portion 41 formed in the metal perforated plate 37 which partitions between the dispensing chamber 23 and the exhaust chamber 21. A bottom portion of the box body 67 is fixed to the lower bracket 65. The bottom portion of the box body 67 has a slight gap with respect to the metal perforated plate 37 defined as the partition plate. The object mounting table 69 is fixedly provided on the box body 67.

Within the box body 67, three rollers 93a, 93b, 93c are, as illustrated in FIG. 13, arranged substantially at equal intervals in the Y-direction in the side-by-side relation rotatably with the axial line being set in the X-direction. The central roller 93b is positioned slightly higher than the rollers 93a, 93c on both sides, and the lower edges of the peripheral surfaces of the rollers 93a, 93c on both sides are substantially flush with the lower surface of the bottom portion of the box body.

On the other hand, a flexible belt 95, which has a size large enough to cover the Y-directional aperture, is stretched on the upper side of the metal perforated plate 37 which partitions between the dispensing chamber 23 and the exhaust chamber 21. The flexible belt 95 is fixed to the metal perforated plate 37 at both ends in the Y-direction. At the bottom portion of the box body 67, this belt 95 passes into the box body 67 through two apertures formed at lower portions of the box body 67 and below the rollers 93a, 93c on both sides and is stretched over to the upper portion of the central roller 93b. The box body 67 is movable in the Y-direction within the Y-directional aperture 41, and at this time the Y-directional aperture 41 is configured to take the sealing structure in the way of being sealed by the belt 95. More perfection of this sealing structure may involve attaching a cover (not illustrated) to the both side surfaces of the box body 67 or the lower side of the object mounting table 69 and sealing the box body 67 by bringing the lower portion of the cover into contact with the metal perforated plate 37 or the belt 95.

According to the first embodiment, with the structure described above, the power transmission mechanisms 49, 51: 61, 63 in the X- and Y-directions as well as the driving motors 47, 59 in the X- and Y-directions are installed outside the dispensing chamber 23, then the object mounting unit including the dispensing device assembly 55 to be driven and the object mounting table 69 may be installed within the dispensing chamber 23, and hence there is no necessity for installing the electric wires and electric devices within the dispensing chamber 23, thereby acquiring the excellent sealing structure.

### Second Embodiment

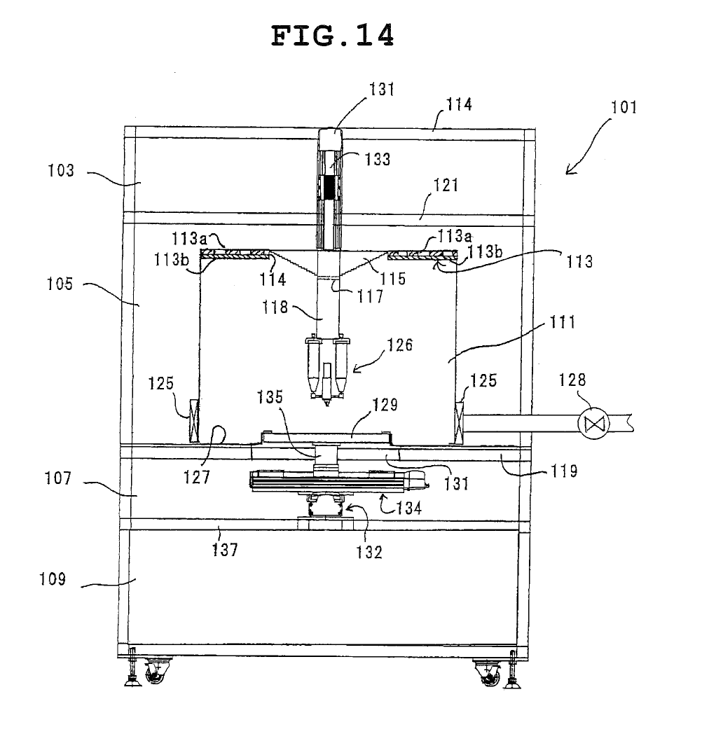

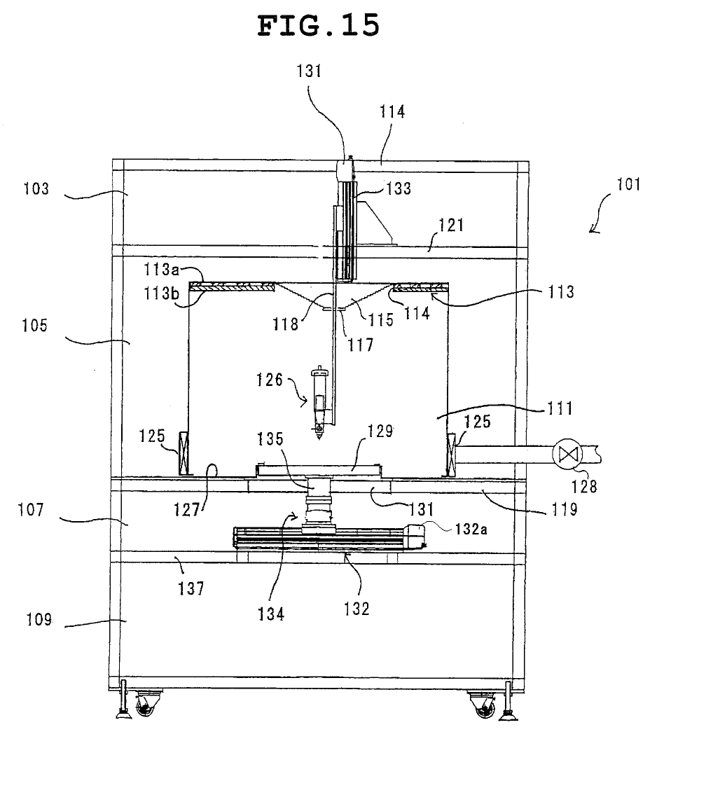

Next, a second embodiment of the present invention will hereinafter be described with reference to FIGS. 14 and 15.

In the second embodiment, FIG. 14 is a schematic sectional view of the interior of the dispensing apparatus as viewed from frontward, and FIG. 15 is a schematic sectional view of the interior of the dispensing apparatus as viewed from sideway.

In the second embodiment, the dispensing apparatus includes an apparatus body 101 taking substantially the cubic shape that is long in the vertical direction on the whole, and the apparatus body 101 includes a front portion, a rear plate, a left side plate, a right side plate, a bottom portion and a top portion. The apparatus body is roughly sectioned into four parts in the vertical direction, which are, from above, an upper chamber 103, a dispensing chamber installation room 105, an XY driving portion installation room 107 provided thereunder and a lower chamber 109. Note that an XY driving portion installation room and the lower chamber may be configured by one room and may also be configured as an open space.

In the second embodiment, within the dispensing chamber installation room 105, a dispensing chamber 111 taking the box shape that is smaller in length, width and height on the whole than the dispensing chamber installation room 105 is fixedly disposed on a partition floor plate member 119 that partitions between the dispensing chamber installation room 105 and the XY driving portion installation room 107.

A top plate member 113 forming a top portion of the dispensing chamber 111 is formed with an aperture 114 taking substantially a circular shape at the central portion, in which there is fixed a bellows member 115 taking a conical shape converging from a peripheral edge of the aperture 114 toward the center downwardly. An annular member 117 is fixedly provided at the central portion of the bellows member 115, and there is provided an elongated plate-like bracket 118 penetrating the annular member 117 in the vertical direction and extending from within the dispensing chamber into the upper chamber 103 provided upwardly. The upper portion of the bracket 118 is fixed to a top plate member 114 of the apparatus body and to a partition plate 121 that partitions between the upper chamber 103 and the dispensing chamber installation room 105 of the apparatus body. Within the dispensing chamber 111, the lower end portion of the bracket 118 is fitted with a dispensing device assembly 126 similar to the dispensing device assembly in the first embodiment. The upper chamber 103 is equipped therein with a motor 131 for driving in the vertical direction (Z-direction) and a driving mechanism 133 which converts the motor driving force into the reciprocating motions in the vertical direction, and the dispensing device assembly 126 is enabled to make the reciprocating motions in the vertical direction (Z-direction) through the bracket 118. Note that the bellows member 115 may be composed of a retractable elastomer material. Further, the top plate member 113 in place of the bellows member 115 may be formed with a hole having a slight gap with respect to the bracket 118 so as to enable the bracket 118 to move vertically, and the gap may also be provided with a seal.

As depicted in FIG. 15, the top plate member 113 of the dispensing chamber 111 includes, similarly to the first embodiment, an external layer 113a of the perforated plate and an internal filter layer 113b, thereby forming the fresh air inlet or intake portion. Note that the air intake may involve installing, into the dispensing chamber 111, a duct with a manual opening/closing dumper serving also to adjust an air flow rate, and adopting a push-pull configuration by providing an air suction fan on the upstream side, which are adopted in many cases in the technical field belonging to the invention of the present application.

In the second embodiment, exhaust ports 125 each provided with a filter are formed in the lower portions of the right/left side plates of the dispensing chamber 111, and an exhaust device 128 is connected via the exhaust ports 125.

An object mounting square table plate 129 building up an object mounting unit is fixed to a central portion of a floor plate member 127 building up the bottom portion of the dispensing chamber 111, and a portion between this table plate 129 and the floor plate member 127 is configured to take the sealing structure. The floor plate member 127 is movable back and forth and right and left with respect to the side plates of the dispensing chamber 111. Hence, the floor plate member 127 has a size enough to build up, even when moving on one side, the bottom portion of the dispensing chamber 111 on the other side, and spaces between the edge of the table plate 129, the front side portion of the dispensing chamber on the side corresponding thereto, the rear side plate and the side plate have sizes enough to allow the movement of the floor plate member 127.

The floor plate member 119 between the dispensing chamber installation room 105 and the XY driving portion installation room 107 is formed with an aperture 131 having a size sufficient for allowing the X- and Y-directional movements of the XY movable body which supports from under the object mounting table plate 129 within the dispensing chamber 111. The undersurface of the object mounting table plate 129 is exposed open to the XY driving portion installation room 107 via this aperture.

A driving force converting transmission mechanism 132 which includes the Y-directional driving motor and a converting mechanism, such as a ball screw mechanism, for converting the rotations of this Y-directional driving motor into the reciprocating linear motions in the Y-direction, is provided at the center of the floor member 137 of the XY driving portion installation room 107. A driving force converting transmission mechanism 134 which includes the X-directional driving motor and a converting mechanism, such as a ball screw mechanism, for converting the rotations of this X-directional driving motor into the reciprocating linear motions in the X-direction is fitted to and supported on the movable member that is moved in the Y-direction by the Y-directional driving force converting transmission mechanism 132. An upper end of the X-directional movable member 135 that is moved in the X-direction by the X-directional driving force converting transmission mechanism 134, configures the XY-directional movable body and fixedly supports the undersurface of the object mounting square table plate 129.

Thus, in the second embodiment also, there is no necessity for installing the electric wires and electric devices within the dispensing chamber 111; the X-, Y- and Z-directional driving motors as well as the X-, Y- and Z-directional power transmission mechanisms are installed outside the dispensing chamber 111; and only the dispensing device assembly to be driven and the object mounting table may be installed within the dispensing chamber 111, thereby acquiring the excellent sealing structure. Further, there is no necessity for heating by the circulation of the heat carrier as in the first embodiment because the undersurface of the table is not exposed to within the dispensing chamber, and an unillustrated cartridge type electric heater etc is incorporated together with a temperature sensor into the table, whereby the table may be heated by controlling its temperature to an arbitrary temperature.

In the conventional dispensing apparatus, the air is sucked naturally from the aperture portion by the forcible exhaust, and hence such a possibility extremely rises that when the dispensing apparatus is installed in the atmosphere other than the clean room, the foreign matters such as the dusts are absorbed and adhered to the object to be coated or coated object, resulting in the extremely high possibility of causing the decline of quality of the coated object. Further, the flow of intake air from the aperture portion causes the turbulent flow in the vicinity of the object to be coated, which becomes the critical defect if the dispensing device is the spray device. In this respect, the dispensing apparatus according to the second embodiment can solve these problems because of obtaining the excellent sealing structure.

In the second embodiment, a door is provided at the front side portion of the dispensing chamber 111 and can be opened and closed to allow the access as in the case of taking the object to be coated and the coated object in and out of the dispensing chamber 111, however, the box body including the top portion, the front side portion, the rear plate and the right/left side plates to build up the dispensing chamber 111 is configured to get removable from the floor plate member 127, and this box body may be moved upward by the motor 131.

### Third Embodiment

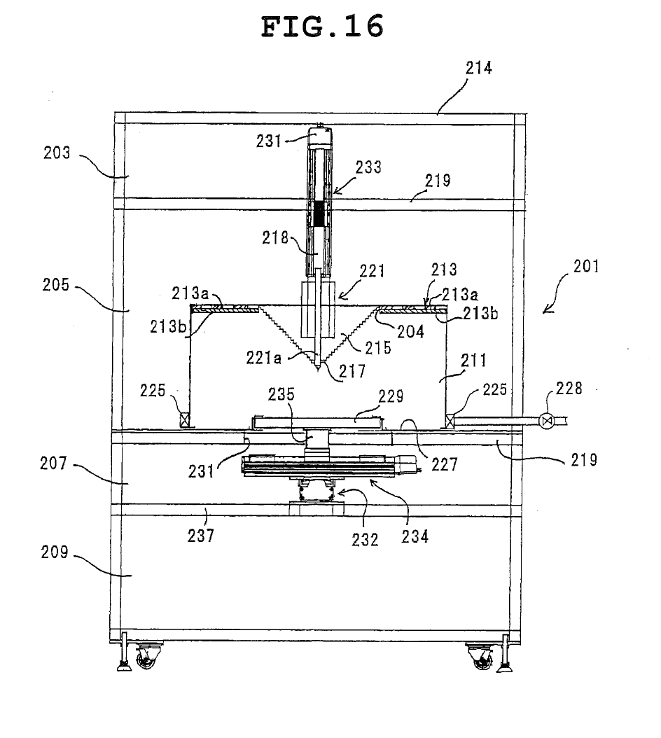

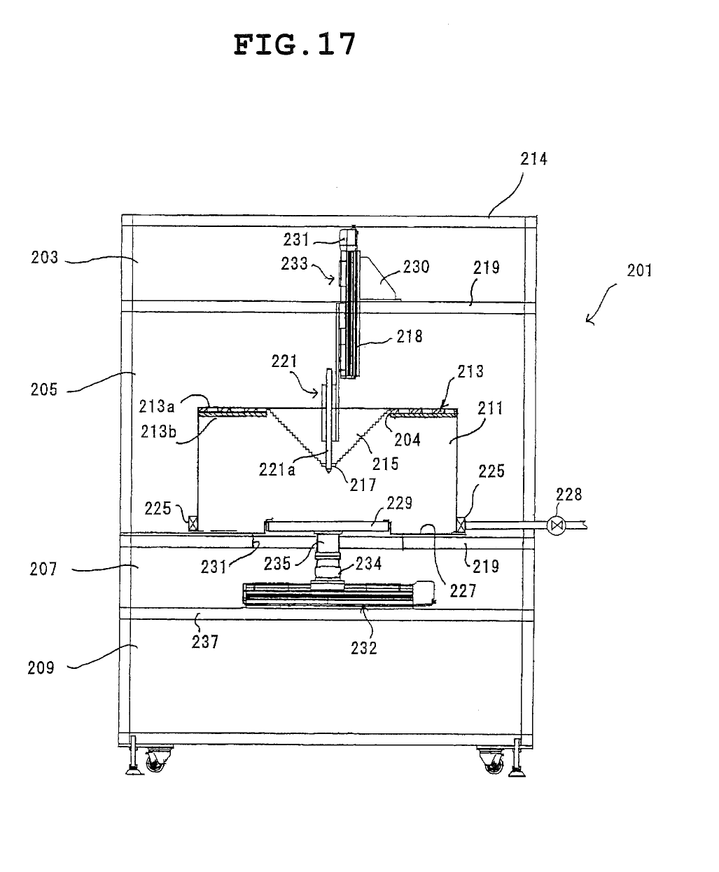

Next, a third embodiment of the present invention will hereinafter be described with reference to FIGS. 16 and 17.

In the third embodiment, FIG. 16 is a schematic sectional view of the interior of the dispensing apparatus as viewed from frontward, and FIG. 17 is a schematic sectional view of the interior of the dispensing apparatus as viewed from sideway.

In the third embodiment, the dispensing apparatus includes an apparatus body 201 taking substantially the cubic shape that is long in the vertical direction on the whole, and the apparatus body 201 includes a front portion, a rear plate, a left side plate, a right side plate, a bottom portion and an top portion. The apparatus body is roughly sectioned into four parts in the vertical direction, which are, from above, an upper chamber 203, a dispensing chamber installation room 205, an XY driving portion installation room 207 provided thereunder and a lower chamber 209. Note that the XY driving portion installation room and the lower chamber may be configured by one room and may also be configured as the open space.

In the third embodiment, within the dispensing chamber installation room 205, a dispensing chamber 211 taking the box shape that is smaller in length, width and height on the whole than the dispensing chamber installation room 205 is fixedly disposed on a floor plate member 219 which partitions between the dispensing chamber installation room 205 and the XY driving portion installation room 207.

A top plate member 213 forming a top portion of the dispensing chamber 211 is formed with an aperture taking substantially a circular shape at the central portion, in which there is fixed a bellows member 215 taking a conical shape converging from a peripheral edge of the aperture toward the center downwardly. An annular member 217 is fixedly provided at the central portion of the bellows member 215.

In the third embodiment, a discharge nozzle 221a is configured so that only a tip end portion of this discharge nozzle penetrates the annular member 217 in the vertical direction and is exposed to within the dispensing chamber 111. By an elongated plate-like bracket 218 extending into the upper chamber 203 provided above or at the upper side of the dispensing chamber, the nozzle body unit exclusive of the tip end portion of the discharge nozzle 221a and a dispensing device assembly 221 supporting the nozzle body unit, are supported so that the nozzle body unit and the dispensing device assembly 221 exist outside the dispensing chamber. The upper portion of the bracket 218 is supported so as to be movable in the vertical direction via a support member 230 by the top plate member 214 of the apparatus body and a floor plate member 219 between the upper chamber 203 and the dispensing chamber installation room 205.

The upper chamber 203 is equipped with a motor 231 for driving in the vertical direction (Z-direction) and a driving mechanism 233 for converting the motor driving force into the reciprocating motions in the vertical direction, in which the bracket 218 is driven by the driving mechanism 233, thereby enabling the dispensing device assembly 221 to make the reciprocating motions in the vertical direction (Z-direction).

The top plate member 213 of the dispensing chamber 211 includes an external layer 213a of the perforated plate and an internal filter layer 213b, thereby forming the fresh air inlet or intake portion. Note that the air intake may involve installing, into the dispensing chamber 211, the duct with the manual opening/closing dumper serving also to adjust the air flow rate, and adopting the push-pull configuration by providing the air suction fan on the upstream side, which are adopted in many cases in the technical field belonging to the invention of the present application.

In the third embodiment, exhaust ports 225 each provided with the filter are formed in the lower portions of the right/left side plates of the dispensing chamber 211, and an exhaust device 228 is connected via the exhaust ports 225.

An object mounting square table plate 229 building up an object mounting unit is fixed to a central portion of a floor plate member 227 building up the bottom portion of the dispensing chamber 211, and a portion between the table plate 229 and the floor plate member 227 is configured to take the sealing structure. The floor plate member 227 is movable back and forth and right and left with respect to the front side portion, the rear plate and the side plates of the dispensing chamber 211. Hence, the floor plate member 227 has a size enough to build up, even when moving on one side, the bottom portion of the dispensing chamber 211 on the other side, and a space between the edge of the table plate 229 and the side plate on the side corresponding thereto has a size enough to allow the movement of the floor plate member 227.

The floor plate member 219 which partitions between the dispensing chamber installation room 205 and the XY driving portion installation room 207 is formed with an aperture 231 having a size sufficient for allowing the X- and Y-directional movements of the XY movable body which supports from under the object mounting table plate 229. The undersurface of the object mounting table plate 229 is exposed to the XY driving portion installation room 207 via this aperture 231.

A driving force converting transmission mechanism 232 which includes the Y-directional driving motor and a converting mechanism, such as a ball screw mechanism, for converting the rotations of this Y-directional driving motor into the reciprocating linear motions in the Y-direction, is provided at the center of the floor member 237 of the XY driving portion installation room 207. A driving force converting transmission mechanism 234 which includes the X-directional driving motor and a converting mechanism, such as a ball screw mechanism, for converting the rotations of this X-directional driving motor into the reciprocating linear motions in the X-direction is fitted to and supported on the movable member moved in the Y-direction by the Y-directional driving force converting transmission mechanism 232. An upper end of the X-directional movable member moved in the X-direction by the X-directional driving force converting transmission mechanism 234, configures the XY-directional movable body 235 and fixedly supports the undersurface of the object mounting square table plate 229.

In the third embodiment, a door may be provided at the front side portion of the dispensing chamber 211 and can be opened and closed to allow the access as in the case of taking the object to be coated and the coated object in and out of the dispensing chamber 211, however, the box body including the top portion, the front side portion, the rear plate and the right/left side plates to build up the dispensing chamber 211 is configured to get removable from the floor plate member 227, and this box body may be moved upward by the motor 231.

Thus, in the third embodiment, there is no necessity for installing the electric wires and the electric devices within the dispensing chamber 211; the X-, Y- and Z-directional driving motors as well as the X-, Y- and Z-directional power transmission mechanisms are installed outside the dispensing chamber; and only the driven dispensing device assembly and the driven object mounting table may be installed within the dispensing chamber, thereby acquiring the excellent sealing structure. Further, there is no necessity for heating by the circulation of the heat carrier as in the first embodiment because the undersurface of the table is not exposed to within the dispensing chamber, and the unillustrated cartridge type electric heater etc is incorporated together with the temperature sensor into the table, whereby the table may be heated by controlling its temperature to an arbitrary temperature.

In the conventional dispensing apparatus, the air is sucked naturally from the aperture portion by the forcible exhaust, and hence such a possibility extremely rises that when the dispensing apparatus is installed in the atmosphere other than the clean room, the foreign matters such as the dusts are absorbed and adhered to the object to be coated or coated object, resulting in the extremely high possibility of causing the decline of quality of the coated object. Further, the flow of intake air from the aperture portion causes the turbulent flow in the vicinity of the object to be coated, which becomes the critical defect if the dispensing device is the spray device. In this respect, the dispensing apparatus according to the third embodiment can solve these problems because of obtaining the excellent sealing structure.

Additionally, in the third embodiment, only the aperture portion of the front edge of the discharge nozzle is exposed to within the dispensing chamber, the dispensing device assembly is installed outside the dispensing chamber, and it is therefore feasible to adopt an electromagnetic gun as a valve of the component of the dispensing device assembly. Therefore, according to the third embodiment, a combinational use of the high-speed electromagnetic valve and a special controller enables the dispensing at the speed as high as, e.g., 50-1000 Hz.

1. A dispensing method of dispensing a coating material over an object to be applied by a dispensing device within a dispensing chamber composed of a top plate, a bottom plate and side plates, the method comprising:
forming a fresh air inlet and an exhaust outlet in an upper portion and a lower portion of the dispensing chamber, respectively;
exposing at least a discharge hole of the dispensing device to within the upper portion of the dispensing chamber;
installing an object mounting unit to be exposed to within the dispensing chamber from the side of the bottom plate and configuring the dispensing device and an object mounting unit so as to enable at least one of the dispensing device and the object mounting unit to move linearly; and
moving at least one of the dispensing device and the object mounting unit with a driving mechanism provided outside the dispensing chamber to position the dispensing device with respect to the object to be applied, and dispensing the coating material over the object to be applied by the dispensing device.

2. The dispensing method according to claim 1, wherein the dispensing chamber takes a box-like shape, an upper portion of the dispensing chamber is formed with the fresh air inlet, and a lower portion of the dispensing chamber is formed with the exhaust outlet;
a first aperture extending in a first linear direction is formed in the top plate, and a second aperture extending in a second linear direction orthogonal to the first linear direction is formed in the bottom plate;
the driving mechanism includes a first driving device that is provided above the top plate and outside the dispensing chamber for moving the dispensing device in the first linear direction and a second driving device provided below the bottom plate outside the dispensing chamber and serving to move the object mounting unit in the second linear direction;
the object mounting unit is exposed to within the dispensing chamber through the second aperture of the bottom plate,
a first movable body is provided to be moved in the first linear direction by the first driving device;
a first bracket is provided at the first movable body to extend into the dispensing chamber through the first aperture of the top plate;
first sealing means is provided between the top plate and the first bracket to seal the first aperture;
a dispensing device assembly equipped with the dispensing device is fitted to the first bracket within the dispensing chamber;
second sealing means is provided between the bottom plate and the object mounting unit to seal the second aperture; and
a control device is provided outside the dispensing chamber to control the first and second driving devices, wherein
the object to be applied is disposed on the object mounting unit within the dispensing chamber, the dispensing chamber exclusive of the fresh air inlet and the exhaust outlet, is sealed, the control device controls the first and second driving devices or positions the dispensing device with respect to the object to be applied by a programmed operation, and the dispensing device dispenses the coating material over the object to be applied.

3. The dispensing method according to claim 2, wherein at least one of the side plates is provided with an opening/closing door for accessing the interior of the dispensing chamber,
the object mounting unit includes: a second movable body that is moved in the second linear direction by the second driving device; a second bracket provided at the second movable body and extending into the dispensing chamber through the second aperture of the bottom plate; and an object mounting table fitted to the second bracket; and
the object to be applied is disposed on the object mounting unit within the dispensing chamber via the opening/closing door.

4. The dispensing method according to claim 2, wherein the object mounting unit includes a belt conveyor that is moved in the second linear direction by the second driving device, and the object to be applied is placed on the belt conveyor and disposed within the dispensing chamber.

5. The dispensing method according to claim 1, wherein the dispensing device is moved in the vertical direction by the second driving mechanism disposed outside the dispensing chamber.

6. The dispensing method according to claim 1, wherein the dispensing chamber configures a cylindrical or polygonal box body including the top plate and the side plates and fixedly disposed to open downward, the bottom plate being disposed on the lower side of the box body and enabled to make linear motions at the same height with the box body in the first direction and in the second direction orthogonal to the first direction in a contact or non-contact state with the side plate,
a dispensing device is disposed above the top plate, of which at least a discharge hole is exposed to within the dispensing chamber,
the object mounting unit includes a table covering a whole area of the central aperture of the bottom plate, the table being fixedly disposed onto the bottom plate and exposed to within the dispensing chamber and moved together with the bottom plate, the table being moved in the first linear direction and the second linear direction by the first driving device and the second driving device each provided outside the dispensing chamber;
the first and second driving devices position the dispensing device with respect to the object to be applied by a programmed operation; and
the dispensing device dispenses a coating material over the object to be applied.

7. The dispensing method according to claim 6, wherein the dispensing device is moved in the vertical direction by the second driving mechanism disposed outside the dispensing chamber.

8. The dispensing method according to claim 1, wherein the coating material is slurry composed of a phosphor, a binder and a solvent; and
the slurry is moved by a pressure difference between two or small-sized containers or/and circulated by use of a pump and is dispensed by the dispensing device consecutively or pulsewise over an LED mounted on the temperature-controlled object mounting unit.

9. The dispensing method according to claim 5, wherein the coating material is slurry composed of a phosphor, a binder and a solvent, and
the slurry is moved by a pressure difference between two or small-sized containers or/and circulated by use of a pump and coated by the dispensing device consecutively or pulsewise over an LED mounted on the temperature-controlled object mounting unit.

10. The dispensing method according to claim 6, wherein the coating material is slurry composed of a phosphor, a binder and a solvent, and
the slurry is moved by a pressure difference between two or small-sized containers or/and circulated by use of a pump and coated by the dispensing device consecutively or pulsewise over an LED mounted on the temperature-controlled object mounting unit.

11. The dispensing method according to claim 7, wherein the coating material is slurry composed of a phosphor, a binder and a solvent; and
the slurry is moved by a pressure difference between two or small-sized containers or/and circulated by use of a pump and dispensed by the dispensing device consecutively or pulsewise over an LED mounted on the temperature-controlled object mounting unit.

12. The dispensing method according to claim 1, wherein a circulation circuit is configured by establishing communicating paths among one small-sized container, the dispensing device and a small-sized pump to circulate the slurry filling the small-sized container and pressurized by a compressed gas; and
the dispensing device dispenses the slurry consecutively or pulsewise over the LED mounted on the temperature-controlled object mounting unit.

13. The dispensing method according to claim 5, wherein a circulation circuit is configured by establishing communicating paths among one small-sized container, the dispensing device and a small-sized pump to circulate the slurry filling the small-sized container and pressurized by a compressed gas; and
the dispensing device dispenses the slurry consecutively or pulsewise over the LED mounted on the temperature-controlled object mounting unit.

14. The dispensing method according to claim 6, wherein a circulation circuit is configured by establishing communicating paths among one small-sized container, the dispensing device and a small-sized pump to circulate the slurry filling the small-sized container and pressurized by a compressed gas, and
the dispensing device dispenses the slurry consecutively or pulsewise over the LED mounted on the temperature-controlled object mounting unit.

15. A dispensing apparatus configured to dispense a coating material over an object to be applied by a dispensing device within a dispensing chamber including a top plate, a bottom plate and side plates, the apparatus comprising:
a fresh air inlet and an exhaust outlet being formed in an upper portion and a lower portion of the dispensing chamber, respectively;
the dispensing device getting at least its discharge hole exposed to within the dispensing chamber;
an object mounting unit being disposed to be exposed to within the dispensing chamber from the side of the bottom plate; and
a driving mechanism being provided outside the dispensing chamber and driving at least one of the dispensing device and the object mounting unit,
wherein the dispensing device is positioned with respect to the object to be applied and dispenses a coating material over the object to be applied.

16. The dispensing apparatus according to claim 15, wherein the dispensing chamber takes a box-like shape, the fresh air inlet is formed in any one of the top plate and the vicinity of the top plate, and the exhaust outlet is formed in the bottom plate and the vicinity of the bottom plate;
a first aperture extending in a first linear direction is formed in the top plate, and a second aperture extending in a second linear direction having an orthogonal relation with the first linear direction is formed in the bottom plate;
the driving mechanism is provided above the top plate and outside the dispensing chamber and includes a first driving device for moving the dispensing device in the first linear direction and a second driving device provided below the bottom plate and outside the dispensing chamber and serving to move the object mounting unit in the second linear direction;
the object mounting unit is exposed to within the dispensing chamber through the second aperture of the bottom plate,
the dispensing apparatus further includes:
a first movable body that is moved in the first linear direction by the first driving device;
a first bracket provided at the first movable body and extending into the dispensing chamber through the first aperture of the top plate;
first sealing means provided between the top plate and the first bracket and sealing the first aperture;
a dispensing device assembly fitted to the first bracket within the dispensing chamber and including the dispensing device;
second sealing means provided between the bottom plate and the object mounting unit and sealing the second aperture; and
a control device provided outside the dispensing chamber and controlling the first and second driving devices;
wherein the object to be applied is disposed on the object mounting unit within the dispensing chamber and sealed, the dispensing chamber excluding the fresh air inlet and the exhaust outlet is sealed, the first and second driving devices are controlled by the control device or operated by programming to position the dispensing device with respect to the object to be applied, and the dispensing device dispenses the coating material over the object to be applied.

17. The dispensing apparatus according to claim 16, wherein at least one of the side plates is provided with an opening/closing door for accessing the interior of the dispensing chamber;
the object mounting unit includes: a second movable body that is moved in the second linear direction by the second driving device, a second bracket provided at the second movable body and extending into the dispensing chamber through the second aperture of the bottom plate, and an object mounting table fitted to the second bracket; and
the object to be applied is disposed on the object mounting unit within the dispensing chamber through the opening/closing door.

18. The dispensing apparatus according to claim 16, wherein the object mounting unit includes a belt conveyor that is moved in the second linear direction by the second driving device, on which belt conveyor the object to be applied is placed and is disposed within the dispensing chamber.

19. The dispensing apparatus according to claim 15, wherein the dispensing device is moved in the vertical direction by the second driving mechanism disposed outside the dispensing chamber.

20. The dispensing apparatus according to claim 15, wherein the dispensing chamber configures a box body including the top plate and the side plates and fixedly disposed to open downward, the bottom plate being disposed on the lower side of the box body and enabled to make linear motions with respect to the box body in a first horizontal direction and in a second horizontal direction in a contact or non-contact state with the side plate;
the dispensing device is disposed above the top plate and gets at least its discharge hole exposed to within the dispensing chamber; and
the object mounting unit includes a table that covers a whole area of the central aperture of the bottom plate and is fixed to the bottom plate and exposed to within the dispensing chamber, the table being moved together with the bottom plate and movable in the first linear direction and the second linear direction by the first driving device and the second driving device each provided outside the dispensing chamber.

21. The dispensing apparatus according to claim 20, further comprising a second driving mechanism disposed outside the dispensing chamber and moving the dispensing device in the vertical direction.

22. The dispensing apparatus according to claim 16, wherein the coating material is slurry composed of a phosphor, a binder and a solvent, and
the slurry is moved by a pressure difference between two or small-sized containers or/and circulated by use of a pump and dispensed by the dispensing device consecutively or pulsewise over an LED mounted on the temperature-controlled object mounting unit.

23. The dispensing apparatus according to claim 19, wherein the coating material is slurry composed of a phosphor, a binder and a solvent, and
the slurry is moved by a pressure difference between two or small-sized containers or/and circulated by use of a pump and dispensed by the dispensing device consecutively or pulsewise over an LED mounted on the temperature-controlled object mounting unit.

24. The dispensing apparatus according to claim 16, wherein a circulation circuit is configured by establishing communicating paths among one small-sized container, the dispensing device and a small-sized pump to circulate the slurry filling the small-sized container and pressurized by a compressed gas, and
the dispensing device dispenses the coating material consecutively or pulsewise over the LED mounted on the temperature-controlled object mounting unit.

25. The dispensing apparatus according to claim 19, wherein a circulation circuit is configured by establishing communicating paths among one small-sized container, the dispensing device and a small-sized pump to circulate the slurry filling the small-sized container and pressurized by a compressed gas, and
the dispensing device dispenses the coating material consecutively or pulsewise over the LED mounted on the temperature-controlled object mounting unit.

26. The dispensing apparatus according to claim 20, wherein a circulation circuit is configured by establishing communicating paths among one small-sized container, the dispensing device and a small-sized pump to circulate the slurry filling the small-sized container and pressurized by a compressed gas, and
the dispensing device dispenses the coating material consecutively or pulsewise over the LED mounted on the temperature-controlled object mounting unit.
